(19) United States
(12) Patent Application Publication
(10) Pub. No.: US 2026/0013345 A1
(43) Pub. Date: Jan. 8, 2026

(54) DISPLAY PANEL AND DISPLAY TERMINAL

(71) Applicant: Wuhan China Star Optoelectronics Semiconductor Display Technology Co., Ltd., Wuhan, Hubei (CN)

(72) Inventor: Minchen DU, Wuhan, Hubei (CN)

(21) Appl. No.: 18/254,870

(22) PCT Filed: May 12, 2023
(86) PCT No.: PCT/CN2023/094027

§ 371 Date: May 29, 2023

(30) Foreign Application Priority Data
Mar. 28, 2023 (CN) 202310317035.7

(51) Int. Cl. H10K 59/131

(52) U.S. Cl. CPC H10K 59/131

(57) ABSTRACT

A display panel includes a first metal layer, a second metal layer, and an anode layer. The first metal layer includes a plurality of data lines extending along a first direction, and the second metal layer includes a plurality of fan-out lines. The anode layer includes anodes. The fan-out line includes a first fan-out segment extending along a second direction and a second fan-out segment extending along the first direction. An orthographic projection of the first fan-out segment on the anode layer does not overlap with the anode, and the first direction is different from the second direction.

### TECHNICAL FIELD

The present application relates to the field of display technology, in particular to a display panel and a display terminal.

### BACKGROUND

OLED (organic light emitting diode) display technology is a new type of display technology, which has gradually attracted people's attention due to its unique advantages such as low power consumption, high saturation, fast response time, and wide viewing angle and occupies a certain position in the field of panel display technology.

FIAA (fanout in AA) is a design solution to solve the difficulty of fan-out (Fanout) line in narrow bezels and ultra-narrow bezels. In the related art, FIAA adopts three-layer metal layer lines or two-layer metal layer lines. Relatively speaking, two-layer metal layer lines can reduce costs. However, after reducing the number of metal layers, there may be insufficient flatness of an anode metal caused by uneven metal lines under the anode, resulting in an issue of screen-off mura (unevenness).

Therefore, there is an urgent need to provide a display panel to improve a mura issue caused by FIAA using two layers of metal layer lines.

### SUMMARY OF INVENTION

The present application provides a display panel and a display terminal to improve the technical problem of screen-off mura caused by FIAA adopting two-layer metal layer lines.

In order to solve the above-mentioned solution, the technical scheme provided by the application is as follows:

The present application provides a display panel, which includes:
a substrate;
a first metal layer disposed on the substrate, wherein the first metal layer comprises a plurality of data lines extending along a first direction, and the data lines are located in a display area of the display panel;
a second metal layer disposed on a side of the first metal layer away from the substrate, wherein the second metal layer comprises a plurality of fan-out lines, the fan-out lines are located in the display area, and one of the fan-out lines is electrically connected to one of the data lines; and
an anode layer disposed on a side of the second metal layer away from the substrate, wherein the anode layer comprises a plurality of anodes disposed separately from each other;
wherein the fan-out line comprises a first fan-out segment extending along a second direction and a second fan-out segment extending along the first direction, wherein the first fan-out segment is connected to the second fan-out segment, an orthographic projection of the first fan-out segment on the anode layer does not overlap with the anode, and an angle between the first direction and the second direction is greater than 0° and less than or equal to 90°.

The present application also provides a display terminal, where the display terminal includes the above-mentioned display panel, and the display panel includes:
a substrate;
a first metal layer disposed on the substrate, wherein the first metal layer comprises a plurality of data lines extending along a first direction, and the data lines are located in a display area of the display panel;
a second metal layer disposed on a side of the first metal layer away from the substrate, wherein the second metal layer comprises a plurality of fan-out lines, the fan-out lines are located in the display area, and one of the fan-out lines is electrically connected to one of the data lines; and
an anode layer disposed on a side of the second metal layer away from the substrate, wherein the anode layer comprises a plurality of anodes disposed separately from each other;
wherein the fan-out line comprises a first fan-out segment extending along a second direction and a second fan-out segment extending along the first direction, wherein the first fan-out segment is connected to the second fan-out segment, an orthographic projection of the first fan-out segment on the anode layer does not overlap with the anode, and an angle between the first direction and the second direction is greater than 0° and less than or equal to 90°.

### DESCRIPTION OF INVENTION

### Brief Description of the Drawings

The technical solutions and other beneficial effects of the present application will be apparent through the detailed description of the specific embodiments of the present application below in conjunction with the accompanying drawings.

FIG. 1 is a schematic top view of a display panel of the present application.

FIG. 2 is a schematic cross-sectional view of a display panel of the present application.

FIG. 3 is a schematic diagram of a routing area of the display panel in FIG. 1.

FIG. 4 is an enlarged schematic view of a partial top view structure at point B in FIG. 1.

FIG. 5 is an enlarged schematic view of another partial top view structure at B in FIG. 1.

FIG. 6 is an enlarged schematic view of a partial top view structure at point C in FIG. 1.

FIG. 7 is an enlarged schematic view of another partial top view structure at point C in FIG. 1.

FIG. 8 is an enlarged schematic view of a partial top view structure at D in FIG. 1.

FIG. 9 is an enlarged schematic view of another partial top view structure at D in FIG. 1.

FIG. 10 is a pixel circuit of the display panel of the present application.

### DETAILED DESCRIPTION OF ILLUSTRATED EMBODIMENTS

The technical solutions in the embodiments of the present application will be clearly and completely described below in conjunction with the drawings in the embodiments of the present application. Apparently, the described embodiments are only some of the embodiments of this application, not all of them. Based on the embodiments in this application, all other embodiments obtained by those skilled in the art without making creative efforts belong to the scope of protection of this application. In addition, it should be understood that the specific implementations described here are only used to illustrate and explain the present application and are not intended to limit the present application. In this application, unless stated to the contrary, the used orientation words such as “up” and “down” usually refer to up and down in the actual use or working state of the device, specifically the direction of the drawing in the drawings. The “inside” and “outside” refer to the outline of the installation.

FIAA (fanout in AA) is a design solution to solve the difficulty of fan-out (Fanout) line in narrow bezels and ultra-narrow bezels. In the related art, FIAA adopts three-layer metal layer lines or two-layer metal layer lines. Relatively speaking, two-layer metal layer lines can reduce costs. However, after reducing the number of metal layers, there may be insufficient flatness of an anode metal caused by uneven metal lines under the anode, resulting in an issue of screen-off mura (unevenness). Therefore, there is an urgent need to provide a display panel to improve the mura issue caused by FIAA using two layers of metal layer lines. The present application proposes the following solutions based on the above technical problems.

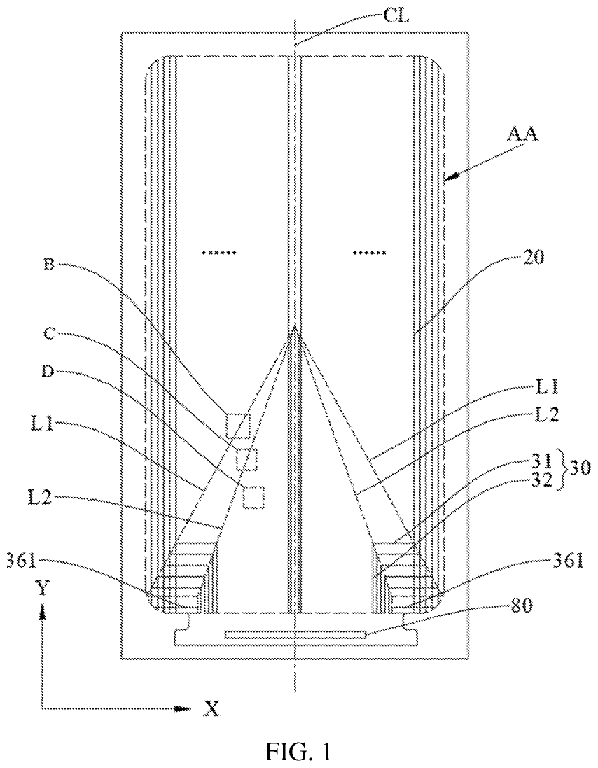

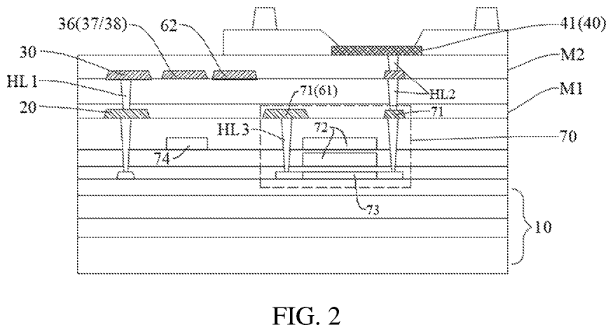

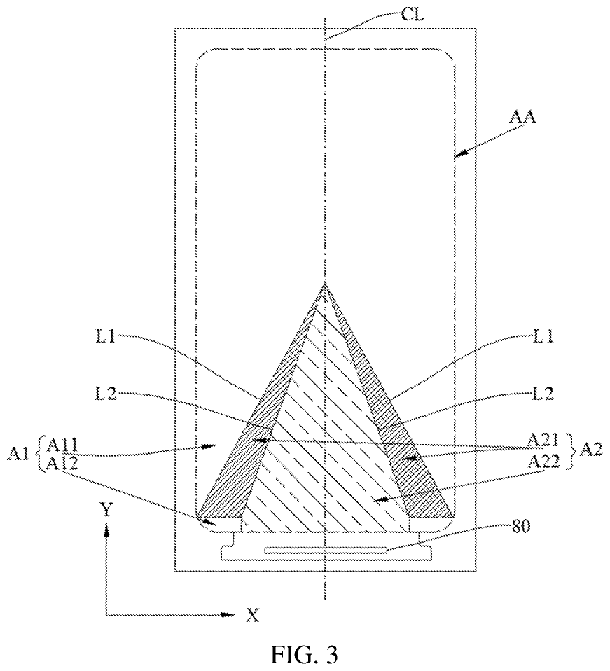

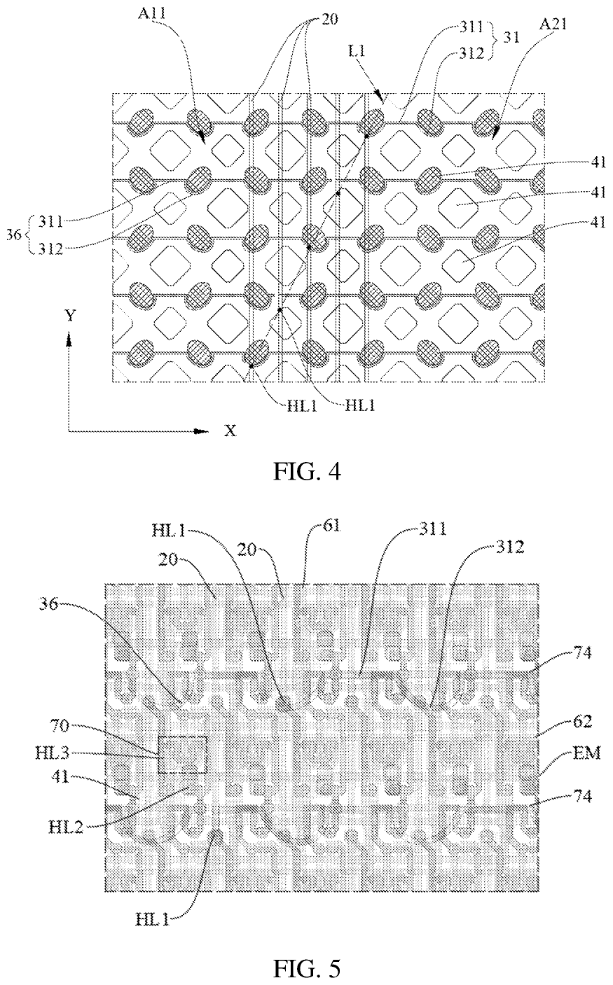

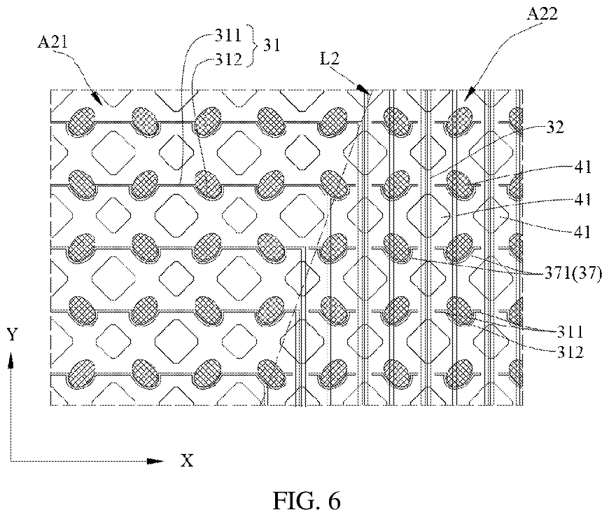

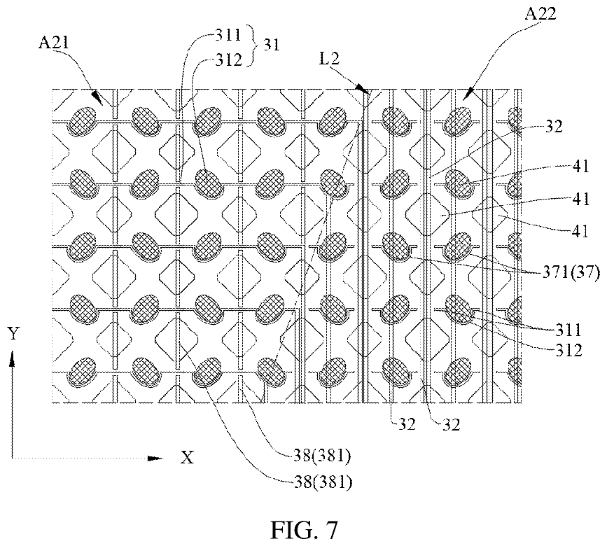

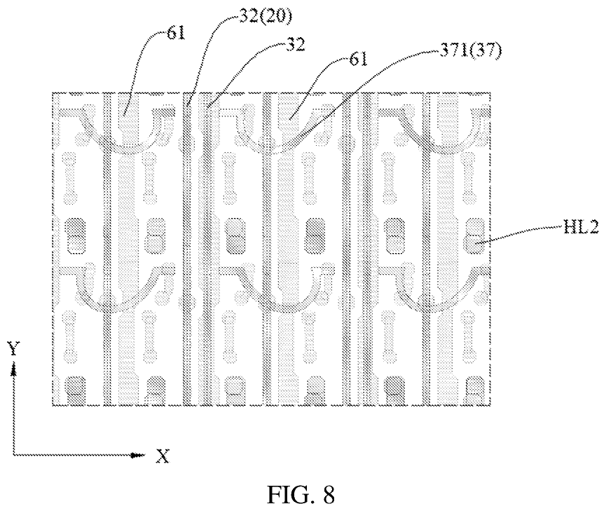

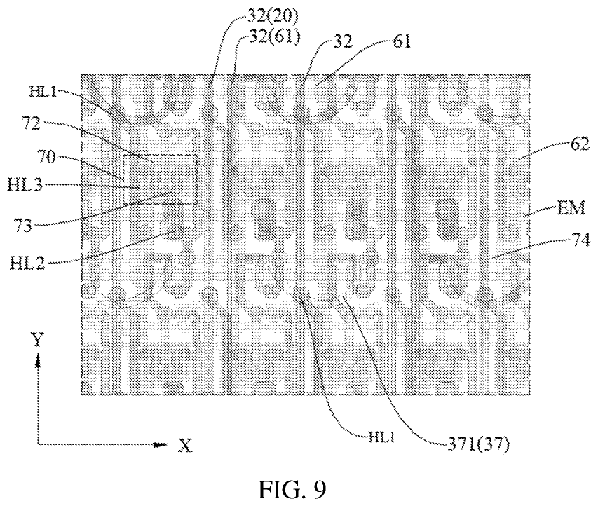

As shown in FIG. 1 to FIG. 9, FIG. 1 is a schematic top view of the display panel of the present application. FIG. 2 is a schematic cross-sectional view of a display panel of the present application. FIG. 3 is a schematic diagram of the routing area of the display panel in FIG. 1. FIG. 4 is an enlarged schematic view of a partial top view structure at point B in FIG. 1. FIG. 5 is an enlarged schematic view of another partial top view structure at B in FIG. 1. FIG. 6 is an enlarged schematic view of a partial top view structure at point C in FIG. 1. FIG. 7 is an enlarged schematic view of another partial top view structure at point C in FIG. 1. FIG. 8 is an enlarged schematic view of a partial top view structure at D in FIG. 1. FIG. 9 is an enlarged schematic view of another partial top view structure at D in FIG. 1.

The present application discloses a display panel. The display panel includes a substrate 10, a first metal layer M1 disposed on the substrate 10, a second metal layer M2 disposed on a side of the first metal layer M1 away from the substrate 10, and a anode layer 40 disposed on a side of the second metal layer M2 away from the substrate 10. The first metal layer M1 includes a plurality of data lines 20 extending along the first direction Y. The data lines 20 are located in a display area AA of the display panel. The second metal layer M2 includes a plurality of fan-out lines 30. The fan-out lines 30 are located in the display area AA. One of the fan-out lines 30 is electrically connected to one of the data lines 20. The anode layer 40 includes a plurality of anodes 41 disposed separately from each other. The fan-out line 30 includes a first fan-out segment 31 extending along a second direction X and a second fan-out segment 32 extending along the first direction Y. The first fan-out segment 31 is connected to the second fan-out segment 32. An orthographic projection of the first fan-out segment 31 on the anode layer 40 does not overlap with the anode 41. An angle between the first direction Y and the second direction X is greater than 0° and less than or equal to 90°.

In this application, the fan-out lines 30 on the second metal layer M2 close to the anode layer 40 are set as the first fan-out segment 31 and the second fan-out segment 32. A projection of the first fan-out segment 31 on the anode layer 40 does not overlap with the anode 41. In this way, unevenness of the anode 41 caused by the first fan-out segment 31 being located directly under the anode 41 is prevented, and reflectivity of the anode 41 in all directions tends to be consistent, so as to improve an uneven picture when a screen is off.

Referring to FIG. 1 and FIG. 2, the display panel includes a substrate 10 and multi-layer film layers stacked with the substrate 10. The substrate 10 may be a flexible substrate or a rigid substrate. For example, the flexible substrate may be polyimide or the like. The rigid substrate can be glass or the like. The substrate 10 may be a multilayer film structure. For example, the substrate 10 may include a stacked structure of a first polyimide layer, a second polyimide layer, a buffer layer, etc., but is not limited thereto.

As shown in FIG. 2, the array layer includes a first metal layer M1 and a second metal layer M2. An insulating layer is disposed between the first metal layer M1 and the second metal layer M2. The second metal layer M2 is located on a side of the first metal layer M1 away from the substrate 10. The first metal layer M1 includes a plurality of data lines 20 extending along the first direction Y. The data lines 20 are located in the display area AA, and the data line 20 is used to provide data signals for the sub-pixels of the display panel.

As shown in FIG. 2, an array layer is disposed on the substrate 10. The array layer includes a plurality of driving transistors 70 distributed in an array, metal lines and the like. The first metal layer M1 may further include source and drain 71 of the driving transistor 70 and the first voltage signal line 61. The first voltage signal line 61 may be used to provide a VDD voltage or the like. As shown in FIG. 5, FIG. 8, and FIG. 9, the first voltage signal line 61 is arranged parallel to and spaced from the data lines 20. By arranging the first voltage signal line 61, the data line 20, and the source and drain 71 on the first metal layer M1 in the same layer, the number of metal layers can be reduced, thereby reducing a thickness of the display panel. In addition, the number of photomasks can also be reduced, reducing production costs.

It should be noted that the positions of the lines in the first metal layer M1 and the second metal layer M2 in FIG. 2 are only for illustration, and do not represent the real positions of the projections of the lines on the substrate 10. The positional relationship of the lines in the cross-sectional view corresponding to each position in the display panel is different. FIG. 2 shows a cross-sectional view of the connection position of the fan-out line 30 and the data line 20 through the first via HL1.

As shown in FIG. 1 and FIG. 2, the second metal layer M2 includes a plurality of fan-out lines 30. The fan-out lines 30 are located in the display area AA, so that the display panel can realize a narrow frame, reducing the area occupied by the fan-out line 30 disposed on a lower frame of the display panel in the related art.

In the present application, the metal lines of the display panel are disposed in the first metal layer M1 and the second metal layer M2 respectively, compared with the solution of arranging the metal lines in the three-layer metal layer in the related art, the cost can be reduced, the line replacement can be reduced, and the metal lines can be simpler.

As shown in FIG. 2, a light emitting layer (not shown in the figure) is disposed on the side of the array layer away from the substrate 10. The light emitting layer includes an anode layer 40. The anode layer 40 includes a plurality of anodes 41 disposed separately from each other. One anode 41 corresponds to one sub-pixel of the display panel. By setting the color of the light-emitting material of the light-emitting layer of the sub-pixel, the sub-pixel can correspondingly emit light of different colors. For example, the sub-pixels may be red sub-pixels, green sub-pixels, and blue sub-pixels. It should be noted that, as shown in FIG. 4, FIG. 6 and FIG. 7, shapes of the sub-pixels of the display panel may be the same or different. For example, the red sub-pixels of the display panel may be square, the green sub-pixels may be oval, and the blue sub-pixels may be square, and the present application does not limit the shape of the sub-pixels of the display panel. When the shapes of the sub-pixels are different, the shape of the outline of the anode 41 is also different.

As shown in FIG. 1, the fan-out line 30 on the second metal layer M2 includes a continuous first fan-out segment 31 and a second fan-out segment 32. The first fan-out segment 31 extends along the second direction X, and the second fan-out segment 32 extends along the first direction Y, that is, the fan-out line 30 includes two segments of line arranged in a bend. The first direction Y is not parallel to the second direction X, and the angle between the first direction Y and the second direction X may be greater than 0° and less than or equal to 90°. It should be noted that the first fan-out segment 31 or the second fan-out segment 32 may be a straight line or a curve, and the extending direction thereof represents the extending direction of the line. It does not mean that every line of the first fan-out segment 31 or the second fan-out segment 32 is parallel to the extending direction.

The orthographic projection of the first fan-out segment 31 of the fan-out line 30 on the anode layer 40 does not overlap with the anode 41. That is to say, the first fan-out segment 31 is not directly below the anode 41. The present application does not limit the relationship between the orthographic projection of the second fan-out segment 32 on the anode layer 40 and the anode 41. The orthographic projection of the second fan-out segment 32 on the anode layer 40 may or may not overlap with the anode 41.

In the embodiment of the present application, the outline of the anode 41 is elliptical for illustration. When the shape of the outline of the anode 41 is different, the shape of the fan-out line 30 can be adaptively adjusted.

The technical solution of the present application will now be described in conjunction with specific embodiments.

In one embodiment, referring to FIG. 1 and FIG. 3, in order to facilitate the description of the display panel of the present application, the display panel is divided into multiple areas. The display panel includes a display area AA and a non-display area located around the display area AA. A binding terminal 80 is provided on the lower side of the display area AA. The binding terminal 80 can be connected to an external circuit, and the binding terminal 80 transmits a signal input by the external circuit to the data line 20, thereby driving the display panel to display images. For example, the binding terminal 80 may be bonded and connected to a chip or a chip-on-chip to provide power and driving signals for the display panel. By arranging a plurality of fan-out lines 30 in the display area AA, the lateral distance between the binding terminal 80 of the display panel and the side frame can be increased, that is, a larger L-cut can be obtained, which is beneficial to the production process.

As shown in FIG. 1 and FIG. 3, the display area AA includes a functional routing area A1 and a fan-out routing area A2. The fan-out routing area A2 is located at an end of the display area AA close to the binding terminal 80, and the fan-out routing area 30 is located in the fan-out routing area A2. As shown in FIG. 4, one end of the first fan-out segment 31 is electrically connected to the data line 20 through the first via HL1. The plurality of first vias HL1 are located on the boundary line L1 between the fan-out routing area A2 and the functional routing area A1.

It should be noted that the boundary line L1 between the fan-out routing area A2 and the functional routing area A1 is an approximate straight line. A plurality of first vias HL1 are located on the boundary line L1 between the fan-out routing area A2 and the functional routing area A1, or part of the first via HL1 is located on the side of the boundary line L1 between the fan-out routing area A2 and the functional routing area A1 close to the fan-out routing area A2. That is to say, all the fan-out lines 30 are located in the fan-out routing area A2.

As shown in FIG. 6, the other end of the first fan-out segment 31 is connected to the second fan-out segment 32. One end of the second fan-out segment 32 is connected to the first fan-out segment 31, and the other end extends along the first direction Y close to the binding terminal 80. An end of the second fan-out segment 32 close to the binding terminal 80 is electrically connected to the binding terminal 80 through a wire. As shown in FIG. 1, the end of the second fan-out segment 32 away from the first fan-out segment 31 coincides with the boundary of the display area AA.

Further, as shown in FIG. 3, the fan-out routing area A2 includes a first routing area A21 and a second routing area A22. The first fan-out segment 31 is located in the first routing area A21, and the second fan-out segment 32 is located in the second routing area A22. The first routing area A21 is adjacent to the second routing area A22. The second routing area A22 is located on a side of the display area AA close to the binding terminal 80. The first routing area A21 is located on both sides of the second routing area A22. As shown in FIG. 6, an inflection point of the first fan-out segment 31 and the second fan-out segment 32 is located on the boundary line L2 between the first routing area A21 and the second routing area A22. It should be noted that the boundary line L2 between the first routing area A21 and the second routing area A22 is an approximate straight line.

As shown in FIG. 3, the first routing area A21 is two triangular areas symmetrical to the center line CL of the display area AA. The second routing area A22 is a triangular area symmetrical to the central line CL. The centerline CL of the display area AA refers to a straight line along the first direction Y and passing through the midpoint of the display area AA. The centerline CL does not really exist.

The boundary line L1 between the first routing area A21 and the functional routing area A1 and the boundary line L2 between the first routing area A21 and the second routing area A22 constitute the boundary of the first routing area A21. Two boundary lines L2 between the first routing area A21 and the second routing area A22 that are symmetrical with respect to the central line CL constitute the boundary of the second routing area A22. The boundary line L1 between the first routing area A21 and the functional routing area A1 refers to an approximate straight line close to the end point of the first fan-out segment 31 away from the second fan-out segment 32. That is to say, the end of the first fan-out segment 31 is electrically connected to the data line 20 through the first via HL1. The end point of the first fan-out segment 31 is located in the fan-out routing area A2, and the end point of the first fan-out segment 31 is distributed near the boundary line L1 between the first routing area A21 and the functional routing area A1. The boundary line L1 between the first routing area A21 and the functional routing area A1 does not really exist.

Similarly, the boundary line L2 between the first routing area A21 and the second routing area A22 is an approximate straight line close to the inflection point (i.e., the connection point) of the first fan-out segment 31 and the second fan-out segment 32. The boundary line L2 between the first routing area A21 and the second routing area A22 does not really exist. Both the first routing area A21 and the second routing area A22 are symmetrical about the central line CL. Therefore, in this application, only the display panel located on one side of the central line CL is described in detail, and the arrangement on the other side corresponds to this.

As shown in FIG. 3, the functional routing area A1 includes a first functional area A11 and a second functional area A12. The first functional area A11 is located on a side of the first routing area A21 away from the binding terminal 80. The second functional area A12 is located on a side of the first routing area A21 close to the binding terminal 80. The boundary line between the second functional area A12 and the first routing area A21 extends along the second direction X. The boundary line between the second functional area A12 and the second routing area A22 extends along the first direction Y. That is to say, the functional routing area A1 is divided into two areas by the first routing area A21 and the second routing area A22, namely the first functional area A11 and the second functional area A12.

In one embodiment, as shown in FIG. 4 and FIG. 6, FIG. 4 shows an enlarged top view structure of the display panel near the first routing area A21. In the figure, the boundary line L1 between the first routing area A21 and the functional routing area A1 divides the display panel into the display area AA on the left and the first routing area A21 on the right.

FIG. 6 shows another enlarged view of the top structure of the display panel near the first routing area A21. The boundary line L2 between the first routing area A21 and the second routing area A22 in the figure divides the drawing into the first routing area A21 on the left and the second routing area A22 on the right. Refer to FIG. 1 or FIG. 3 for the positions of the boundary line L1 between the first routing area A21 and the functional routing area A1 and the boundary line L2 between the first routing area A21 and the second routing area A22 in FIG. 4 and FIG. 6. The first fan-out segment 31 includes a plurality of alternately arranged first segments 311 and second segments 312. The first segment 311 is connected to the second segment 312. One of the second segments 312 is corresponding to one of the anodes 41. The orthographic projection of the second segment 312 on the anode layer 40 is disposed on the periphery of the anode 41. The first segment 311 may be a straight line, and the extension of the first segment 311 intersects the anode 41.

Optionally, the orthographic projection of the first segment 311 on the first metal layer M1 may overlap with part of the metal lines on the first metal layer M1, so as not to reduce the aperture ratio of the display panel.

Further, in one embodiment, the orthographic projection of the second segment 312 on the anode layer 40 is spaced apart from the anode 41. The shape of the second segment 312 is the same as the part of the outer contour of the corresponding anode 41. This means that the shape of the second segment 312 corresponds to the shape of the outer contour of the anode 41. As shown in FIG. 4 and FIG. 6, when the shape of the anode 41 is an ellipse, the shape of the second segment 312 is an ellipse spaced from the anode 41. When the shape of the anode 41 is other shapes, the shape of the second segment 312 also changes with the shape of the anode 41, so that the second segment 312 still has the same shape as the part of the outer contour of the anode 41. The orthographic projection of the second segment 312 on the anode layer 40 is spaced apart from the anode 41. The separation distance can be adjusted as needed. In the case of satisfying the precision of the manufacturing process, the separation distance is minimized. For example, the separation distance may be 1 micron. Through the above arrangement, the second segment 312 is not located directly under the anode 41, so as to prevent the second segment 312 from causing unevenness of the film layer under the anode 41. By making the separation distance smaller, the second segment 312 is not located directly under other adjacent anodes 41, so that the aperture ratio of the display panel is not reduced.

Furthermore, as shown in FIG. 4, in one embodiment, the extension line of the first segment 311 passes through the geometric center of the anode 41, so that the distance between the orthographic projection of the first segment 311 on the anode layer 40 and other adjacent anodes 41 in the first direction Y is larger, so as not to reduce the aperture ratio of the display panel.

In one embodiment, referring to FIG. 4, an end of the first fan-out segment 31 away from the second fan-out segment 32 is electrically connected to the data line 20 through a first via HL1. The orthographic projection of the first via HL1 on the second metal layer M2 of one of the adjacent two first fan-out segments 31 overlaps with the second segment 312. The orthographic projection of the first via HL1 on the second metal layer M2 of the other one of the adjacent two first fan-out segments 31 is spaced apart from the first segment 311.

FIG. 4 only shows a part of the data lines 20 to illustrate the connection manner between the data lines 20 and the first fan-out segment 31. The data line 20 is connected to the first fan-out segment 31 through the first via HL1. The first vias HL1 are distributed near the boundary line L1 between the first routing area A21 and the functional routing area A1. When one end of the first fan-out segment 31 is a repeated metal pattern, it is easy to cause uneven macroscopic visibility. Therefore, in this embodiment, the patterns at the end points of two adjacent first fan-out segments 31 are set to be different. As shown in FIG. 4, in any two adjacent first fan-out segments 31, the orthographic projections of the first vias HL1 on the second metal layer M2 are respectively located on the second segment 312 and outside the first segment 311. When the first via HL1 is located outside the first segment 311, the first segment 311 is connected to the first via HL1 after extending in the first direction Y through a section of wiring. Thus, the electrical connection between the first segment 311 and the data line 20 on the first metal layer M1 is realized.

Through the above arrangement, the patterns of the ends of two adjacent first fan-out segments 31 connected to the first via HL1 can be different, thereby reducing the uneven visibility of the macro picture caused by repeated patterns. Refer to FIG. 2 for a cross-sectional view of the connection between the first fan-out segment 31 and the data line 20 through the first via HL1.

It should be noted that, the pattern periodic arrangement of the end of the first fan-out segment 31 connected to the first via HL1 can be set as required and is not limited to the manner shown in FIG. 4. For example, two adjacent first fan-out segments 31 may be used as a repetition period, or four adjacent first fan-out segments 31 may be used as a repetition period, and so on. The use of different repetition periods does not affect the realization of the technical effect and can reduce the uneven visibility of the macro picture caused by the repeated pattern at the end where the first fan-out segment 31 is connected to the first via HL1.

The pixels in the display area AA of the display panel are distributed in an array. Therefore, the film layer structures in the functional routing area A1 and the fan-out routing area A2 are basically the same. The difference is that the fan-out routing area A2 has more fan-out lines 30 than the functional routing area A1. The fan-out lines 30 are used to transmit the external signal input by the binding terminal 80 to the data line 20 in the entire display area AA. Because the fan-out line 30 is located on the second metal layer M2 and is closer to the light-emitting surface of the display panel, the metal reflection of the fan-out line 30 may be perceived by human eyes when the screen is turned off. There is no fan-out line 30 in the functional routing area A1, and the pattern of the second metal layer M2 is different from that of the second metal layer M2 in the fan-out routing area A2. This results in different visual effects generated by the reflection of the second metal layer M2 in the two areas, which aggravates the mura when the screen is turned off.

In response to this, in one embodiment, referring to FIG. 2 and FIG. 4, the second metal layer M2 further includes a plurality of first functional lines 36 extending along the second direction X. The first functional line 36 is located in the first functional area A11. One of first fan-out segments 31 corresponds to and is separately disposed from one of the first functional lines 36. A shape of the first functional line 36 is the same as a sharp of the first fan-out segment 31.

Referring to FIG. 4, the left side of the boundary line L1 between the first routing area A21 and the functional routing area A1 shows the first functional line 36. The first functional line 36 is insulated and is disposed separately from the first fan-out segment 31. The shape of the first functional line 36 is the same as the sharp of the first fan-out segment 31. That is to say, the first functional line 36 also includes a first segment 311 and a second segment 312. The first segment 311 and the second segment 312 are arranged consecutively. The second segment 312 corresponds to an anode 41, and the second segment 312 is located at the periphery of the anode 41. The first segment 311 in the first functional line 36 is at least partially collinear with the first segment 311 in the first fan-out segment 31. The shape of the second segment 312 is the same as the shape of part of the outer contour of the anode 41.

Through the above arrangement, the film layer patterns of the second metal layer M2 in the first functional area A11 of the display panel and the second metal layer M2 in the first routing area A21 can be made close. Therefore, the visual effect of metal reflection on the second metal layer M2 is consistent, and the mura is reduced when the screen is turned off.

In some embodiments, the first functional line 36 and the first fan-out segment 31 can be formed by the same patterning process, thereby simplifying the manufacturing process of the display panel.

It should be noted that setting the first functional wiring 36 can be used to improve mura when the screen is turned off, and the first functional line 36 itself does not need to transmit signals. In one embodiment, in order to prevent the first functional line 36 from interfering with other signals, the first functional line 36 may be connected to a constant voltage. For example, the first functional line 36 may be connected to the VDD voltage.

In one embodiment, as shown in FIG. 1, the second metal layer M2 further includes a plurality of first functional branch lines 361 extending along the second direction X. The first functional branch line 361 is located in the second functional area A12. The shape of the first functional branch line 361 is the same as a sharp of the first fan-out segment 31. The distance between two adjacent first functional branch lines 361 in the first direction Y is the same as the distance between two adjacent first fan-out segments 31 in the first direction Y. That is to say, the pattern of the first functional branch line 361 is the same as the pattern of the first fan-out segment 31.

Through the above arrangement, the film layer patterns of the second metal layer M2 in the second functional area A12 of the display panel and the second metal layer M2 in the first routing area A21 can be made close. Therefore, the visual effect of metal reflection on the second metal layer M2 is consistent, and the mura is reduced when the screen is turned off.

In one embodiment, referring to FIG. 6, the second metal layer M2 further includes a plurality of second functional lines 37 extending along the second direction X. The second functional line 37 is located in the second routing area A22. One of the first fan-out segments 31 is corresponding to and separately arranged from one of the second functional lines 37. The shape of the second functional line 37 is the same as a shape of the first fan-out segment 31.

The second functional line 37 includes a plurality of first functional segments 371 separately arranged from each other. One first functional segment 371 corresponds to one anode 41.

It should be noted that referring to FIG. 6, the second fan-out segment 32 extends along the first direction Y. The second functional line 37 extends along the second direction X. The second fan-out segment 32 and the second functional line 37 are located on the second metal layer M2. Therefore, the second functional line 37 is divided into a plurality of first functional segments 371 to prevent signal crosstalk between the second functional line 37 and the second fan-out segment 32.

The shape of the second functional line 37 is the same as the shape of the first fan-out segment 31. That is, the second functional line 37 also includes a plurality of alternating first segments 311 and second segments 312. The first segment 311 is connected to the second segment 312. The first segment 311 of the second functional line 37 is at least partially collinear with the first segment 311 of the first fan-out segment 31. Different from the first functional line 36, the second functional line 37 is divided into a plurality of first functional segments 371. Each first functional segment 371 includes a second segment 312 and a part of the first segment 311 respectively connected to two ends of the second segment 312.

Through the above arrangement, the film pattern of the second metal layer M2 in the second routing area A22 of the display panel is close to the film pattern of the second metal layer M2 in the first routing area A21. Therefore, the visual effect of metal reflection on the second metal layer M2 is consistent, and the mura is reduced when the screen is turned off.

In one embodiment, referring to FIG. 6, a plurality of first functional segments 371 at least partially located in the first direction Y intersect and connect with a second fan-out segment 32, and at least two second fan-out segments 32 are located between two adjacent first functional segments 371.

Specifically, the second fan-out segment 32 includes at least two arrangements. The two arrangements are periodically distributed. The first arrangement is that a second fan-out segment 32 intersects and connects with the first functional segment 371. The second arrangement is that two second fan-out segments 32 are located between two adjacent first functional segments 371. When a second fan-out segment 32 adopts the first arrangement, the second fan-out segment 32 extends downward along the first direction Y, and passes through the plurality of first functional segments 371 arranged along the first direction Y. Because the second fan-out segment 32 and the plurality of first functional segments 371 are located on the second metal layer M2, the second fan-out segment 32 intersects with the plurality of first functional segments 371 to realize electrical connection. The second fan-out segments 32 located on both sides of the second fan-out segment 32 may be in the second arrangement. That is, the two second fan-out segments 32 are located between two adjacent first functional segments 371 along the second direction X, that is, the two second fan-out segments 32 do not intersect the first functional segments 371.

It should be noted that the second fan-out segment 32 adopts at least two arrangements. Therefore, the second functional line 37 is divided into a plurality of separate first functional segments 371, thereby avoiding short circuits between two adjacent second fan-out segments 32.

The second fan-out segment 32 and the first functional segment 371 may be arranged in other periodic manners. It should be noted that one first functional segment 371 is electrically connected to at most one second fan-out segment 32, so as to prevent short circuit between multiple second fan-out segments 32.

In one embodiment, referring to FIG. 7, the second metal layer M2 further includes a plurality of third functional lines 38 extending along the first direction Y. One second fan-out segment 32 is corresponding to and is separately arranged from one third functional line 38. The third functional line 38 includes a plurality of second functional segments 381 separately arranged from each other. The second functional segment 381 is located between two adjacent first fan-out segments 31.

The third functional line 38 is located in the functional routing area A1 and/or the first routing area A21. That is to say, the third functional line 38 can only be provided in the functional routing area A1. Alternatively, the third functional line 38 may only be provided in the first routing area A21. Alternatively, the third functional line 38 is disposed in the functional routing area A1 and the first routing area A21. It should be noted that the third functional line 38 is not provided in the second routing area A22.

In the first routing area A21, the shape of the third functional line 38 is the same as the shape of the second fan-out segment 32, and the third functional line 38 is located on the extension line of the second fan-out segment 32. For example, the third functional line 38 may be a straight line. The third functional line 38 located between two adjacent first fan-out segments 31 includes a plurality of second functional segments 381 arranged separately from each other, so as to prevent short circuit between the third functional line 38 and the first fan-out segments 31.

In one embodiment, in the functional routing area A1, the orthographic projection of the third functional line 38 on the first metal layer M1 overlaps with the data line 20, so as not to reduce the aperture ratio of the display panel.

Through the above arrangement, the film layer patterns of the functional routing area A1 and the first routing area A21 of the display panel can be made close to the second routing area A22. In this way, the visual effect of metal reflection on the second metal layer M2 in the functional routing area A1 and the fan-out routing area A2 is consistent, and the mura is reduced when the screen is turned off.

In the above embodiment, as shown in FIG. 7, the third functional line 38 in the first routing area A21 is located between two adjacent first fan-out segments 31. Therefore, the third functional line 38 is divided into a plurality of second functional segments 381. In the functional routing area A1, the third functional line 38 can be arranged continuously along the first direction Y. Therefore, the length of any third functional line 38 located in the first routing area A21 is shorter than the length of any third functional line 38 located in the functional routing area A1.

It should be noted that any one or more of the first functional line 36, the first functional branch line 361, the second functional line 37, and the third functional line 38 can be selected as required. The closer the film pattern of the second metal layer M2 in each area in the display area AA is, the better the effect of alleviating the mura is when the screen is turned off.

In one embodiment, the display panel further includes a constant-voltage high-level signal (not shown). The constant-voltage high-level signal can be input through the binding terminal 80 and input into the display area AA through the wiring on the periphery of the display area AA. In order to prevent the first functional line 36, the first functional branch line 361, and the third functional line 38 from interfering with the signal of the display panel, and the first functional line 36, the first functional branch line 361, and the third functional line 38 may be connected to the constant-voltage high-level signal. The constant-voltage high-level signal can provide VDD voltage and the like.

It should be noted that the second functional line 37 is electrically connected to the second fan-out segment 32. Therefore, the second functional line 37 does not need to be electrically connected to the constant-voltage high-level signal.

As shown in FIG. 2, in one embodiment, the constant-voltage high-level signal can be connected to the first voltage signal line 61 of the first metal layer M1 and the second voltage signal line 62 of the second metal layer M2. Thus, the VDD voltage is provided for the first voltage signal line 61 and the second voltage signal line 62. As shown in FIG. 5, FIG. 5 is an enlarged schematic view of another partial top view structure at B in FIG. 1. Compared with FIG. 4, FIG. 5 shows more film layers of the display panel. The data lines 20 on the first metal layer M1 extend along the first direction Y. The first voltage signal lines 61 arranged on the same layer extend along the first direction Y. The data lines 20 are spaced apart from and parallel to the first voltage signal lines 61. The first fan-out segment 31 extends along the second direction X. The second voltage signal line 62 is parallel to the second direction X.

In one embodiment, as shown in FIG. 6 and FIG. 7, the inflection points of the first fan-out segment 31 and the second fan-out segment 32 are located on the first segment 311 or the second segment 312. For example, one of the two adjacent inflection points is on the first segment 311, and the other is on the second segment 312. The positions of the inflection points may also adopt other periodic arrangements. Through the above arrangement, the patterns at the inflection points of two adjacent fan-out lines 30 can be made different, thereby reducing the uneven visibility of the macro picture caused by repeated patterns.

In one embodiment, referring to FIG. 4 and FIG. 6, the display panel includes a plurality of sub-pixels distributed in an array. The orthographic projection of the first fan-out segment 31 on the anode layer 40 is located at the periphery of the anodes 41 of the sub-pixels of the same color. As shown in FIG. 4 and FIG. 6, the display panel includes sub-pixels of three shapes. Sub-pixels of the same shape have the same color. The orthographic projection of the first fan-out segment 31 on the anode layer 40 is located at the periphery of the anode 41 of the sub-pixels of the same color. Therefore, the pattern distribution of the lines in the first fan-out segments 31 tends to be consistent, forming a uniform line structure, thereby improving the uniformity of the metal pattern and solving the issue of uneven when the screen is turned off.

Optionally, the sub-pixels include red sub-pixels, green sub-pixels, and blue sub-pixels. The oval-shaped anode 41 may be a green sub-pixel. The orthographic projection of the first fan-out segment 31 on the anode layer 40 is located at the periphery of the green sub-pixel, so that the pattern distribution of the lines of the first fan-out segment 31 tends to be consistent. This reduces the difference in flatness of the metal of the anode 41 between areas and improves the issue of uneven when the screen is turned off caused by the unevenness of the anode 41.

In one embodiment, the first fan-out segment 31 may be disposed on the periphery of sub-pixels of other colors. For example, the first fan-out can be set on the periphery of the square sub-pixel. Correspondingly, the first segment 311 may be a straight line along the second direction X, and the second segment 312 may be arranged around a part of the outer contour of the square sub-pixel. The present application does not limit the shape of the anode 41, and correspondingly, the shape of the second segment 312 is not limited either.

Optionally, the shape of the anode 41 can be axisymmetric, so that the reflectivity of the anode 41 in multiple directions tends to be consistent, and the issue of uneven when the screen is turned off caused by the asymmetric pattern of the anode 41 is improved.

Optionally, the shape of the anode 41 may be center-symmetric. In this way, the light reflectivity of the anode 41 in all directions tends to be consistent, and the problem of uneven when the screen is turned off caused by the asymmetric pattern of the anode 41 is improved.

In one embodiment, as shown in FIG. 2, FIG. 5, and FIG. 9, the display panel further includes a plurality of driving transistors 70 distributed in an array. The driving transistor 70 includes an active part 73, a gate 72, and a source and drain 71. The active part 73 is disposed on the substrate 10. The gate 72 is disposed on a side of the active part 73 away from the substrate 10. The source and drain 71 are disposed on a side of the gate 72 away from the substrate 10. The source and drain 71 are located on the first metal layer M1. The source and drain 71 are electrically connected to the anode 41 through the second via HL2.

It should be noted that the pixel circuits of the display panels shown in FIG. 5 and FIG. 9 are of 7T1C structure, and the pixel circuits of the display panel may also be of other structures, such as 7T2C. The difference of the pixel circuit does not affect the realization of the present invention.

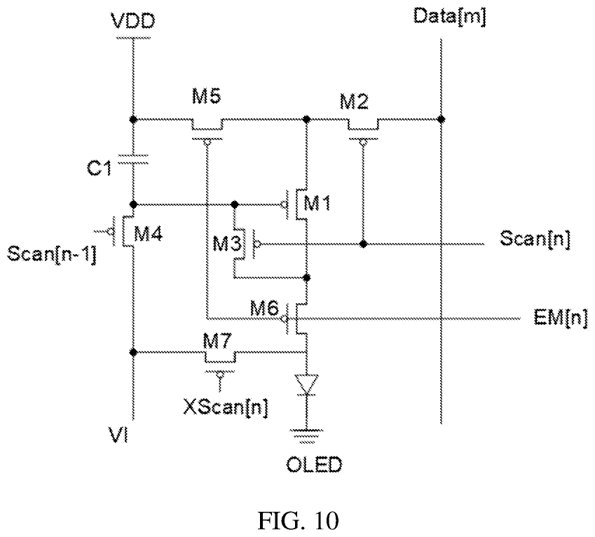

In FIG. 10, a 7T1C pixel circuit is taken as an example for illustration. The 7T1C pixel circuit includes 7 thin film transistors (namely M1-M7) and 1 storage capacitor C1. The thin film transistors include one driving transistor 70 (corresponding to M1 in FIG. 10) and six switch transistors (corresponding to M2 to M7 in FIG. 10). Only the driving transistor 70 is marked in FIG. 5. The driving transistor 70 controls the driving current of the light emitting layer. The switch transistors M2-M7 are used to control the on and off of the circuit.

As shown in FIG. 10, the light emitting process of the display panel includes three stages. In the first stage, input signals to Scan[n−1] and Xscan[n], so that the switch transistor M4 and the switch transistor M7 are turned on. The gate voltage of the switch transistor M1 is pulled down and the storage capacitor C1 is discharged, so as to subsequently charge the storage capacitor C1 and reset the anode 41. In the second stage, the write data line 20 inputs the Data signal, inputs the signal to Scan[n], and turns on the switch transistor M2 and the switch transistor M3. The threshold voltage Vth of the driving transistor 70 and the Data signal are stored in the storage capacitor C1. In the third stage, a light emitting signal EM [n] is given to turn on the switch transistor M5 and the switch transistor M6. The voltage across the storage capacitor C1 controls the driving transistor 70 to turn on, and the OLED emits light.

The source and drain of the driving transistor 70 include a source and a drain electrically connected to both ends of the active part 73, respectively. The source of the driving transistor 70 is connected to the first voltage signal line 61 through the third via HL3. A VDD signal is input to the driving transistor 70. The drain of the driving transistor 70 is electrically connected to the anode 41 through the second via HL2 for controlling the light emitting layer to emit light. The storage capacitor C1 is connected in series between the gate 72 and the source of the driving transistor 70.

As shown in FIG. 5, FIG. 9, and FIG. 10, a switch transistor M6 is further included between the driving transistor 70 and the second via HL2. The light emitting signal (EM) can control the turn-on and turn-off between the drain of the switch transistor M6 and the anode 41.

Further, as shown in FIG. 2, FIG. 5, FIG. 9, and FIG. 10, the display panel further includes an anode reset line 74 extending along the second direction X (corresponding to VI in FIG. 10). The anode reset line 74 is connected to the switching transistor M4 for resetting the anode 41. The anode reset line 74 is set on the same layer as the gate 72. The orthographic projection of the first fan-out segment 31 on the substrate 10 partially overlaps the orthographic projection of the anode reset line 74 on the substrate 10.

It should be noted that, in some embodiments, the orthographic projection of the first fan-out segment 31 on the substrate 10 may overlap with the orthographic projections of other lines on the substrate 10. When the orthographic projection of the first fan-out segment 31 on the substrate 10 overlaps with the orthographic projections of other lines on the substrate 10, the wiring space of the display panel can be saved without reducing the aperture ratio of the display panel.

In all the above-mentioned embodiments, as shown in FIG. 6 and FIG. 7, the second fan-out segment 32 may be a straight line. As shown in FIG. 1, the length of the second fan-out segment 32 increases gradually along the two sides of the display panel in the second direction X toward the center line CL of the display panel.

In one embodiment, the first metal layer M1 further includes first voltage signal lines 61 arranged parallel to and spaced from the data lines 20. At least part of the orthographic projection of the second fan-out segment 32 on the first metal layer M1 overlaps part of the data lines20 and/or part of the first voltage signal line 61.

Referring to FIG. 8 and FIG. 9, which illustrate the film layer structure in the second routing area A22 of the display panel. FIG. 8 shows the structure of a part of the film layer, and FIG. 9 shows the structure of another part of the film layer. Referring to FIG. 8, the first metal layer M1 includes data lines 20 and first voltage signal lines 61 arranged in parallel and spaced apart from each other. The data line 20 is used to provide data signals for the sub-pixels. The first voltage signal line 61 is used to provide a voltage signal. For example, the first voltage signal line 61 may provide a VDD voltage. The orthographic projection of part of the second fan-out segment 32 on the substrate 10 overlaps with the orthographic projection of the data line 20 on the substrate 10, and/or the orthographic projection of part of the second fan-out segment 32 on the substrate 10 overlaps with the orthographic projection of the first voltage signal line 61 on the substrate 10. Therefore, the wiring space of the display panel can be saved without reducing the aperture ratio of the display panel.

The first voltage signal line 61 may be electrically connected to the voltage signal of the display panel. The first functional line 36 and the third functional line 38 may be electrically connected to the first voltage signal line 61 through vias.

In some embodiments, as shown in FIG. 2, FIG. 5, and FIG. 9, the display panel further includes a second voltage signal line 62 located on the second metal layer M2. The second voltage signal line 62 may be electrically connected to a constant voltage high level signal. The second voltage signal line 62 may be used to provide a VDD voltage. The first functional line 36 and the third functional line 38 may be electrically connected to the second voltage signal line 62.

Specifically, referring to FIG. 9, which shows the orthographic projection of each film layer of the display panel on the substrate 10. The data line 20 on the first metal layer M1 at least partially overlaps with the second fan-out segment 32 of the fan-out line 30 on the second metal layer M2. The first voltage signal line 61 on the first metal layer M1 at least partially overlaps with the second fan-out segment 32 of the fan-out line 30 on the second metal layer M2. The first segment 311 on the second metal M2 at least partially overlaps with the anode reset line 74. Through the above arrangement, the aperture ratio of the display panel may not be reduced.

The present application also provides a display terminal, which includes the above-mentioned display panel.

In this embodiment, the display terminal may be any product or component with a display function such as a mobile phone, a tablet computer, a television, a monitor, a notebook computer, a digital photo frame, a navigator, and the like.

In the foregoing embodiments, the descriptions of each embodiment have their own emphases. For parts not described in detail in a certain embodiment, reference may be made to relevant descriptions of other embodiments.

A display panel and a display terminal provided in the embodiments of the present application have been introduced in detail above. In the descriptions, specific examples are used to illustrate the principles and implementation methods of the present application. The descriptions of the above embodiments are only used to help understand the technical solutions and core ideas of the present application. Those of ordinary skill in the art should understand that they can still modify the technical solutions described in the foregoing embodiments or perform equivalent replacements for some of the technical features. However, these modifications or replacements do not make the essence of the corresponding technical solutions depart from the scope of the technical solutions of the embodiments of the present application.

1. A display panel, comprising:
a substrate;
a first metal layer disposed on the substrate, wherein the first metal layer comprises a plurality of data lines extending along a first direction, and the data lines are located in a display area of the display panel;
a second metal layer disposed on a side of the first metal layer away from the substrate, wherein the second metal layer comprises a plurality of fan-out lines, the fan-out lines are located in the display area, and one of the fan-out lines is electrically connected to one of the data lines; and
an anode layer disposed on a side of the second metal layer away from the substrate,
wherein the anode layer comprises a plurality of anodes disposed separately from each other;
wherein the fan-out line comprises a first fan-out segment extending along a second direction and a second fan-out segment extending along the first direction, wherein the first fan-out segment is connected to the second fan-out segment, an orthographic projection of the first fan-out segment on the anode layer does not overlap with the anode, and an angle between the first direction and the second direction is greater than 0° and less than or equal to 90°.

2. The display panel according to claim 1, wherein the display panel comprises a binding terminal located on one side of the display area, the display area comprises a functional routing area and a fan-out routing area, and the fan-out routing area is located in the display area close to one end of the binding terminal;
wherein the fan-out lines are located in the fan-out routing area, the first fan-out segment is connected to the data lines through a plurality of first vias, the first vias are located on a boundary line between the fan-out routing area and the functional routing area, and one end of the second fan-out segment away from the first fan-out segment coincides with a boundary of the display area.

3. The display panel according to claim 2, wherein the fan-out routing area comprises a first routing area and a second routing area, and the functional routing area comprises a first functional area and a second functional area;
wherein the first routing area is located on both sides of the second routing area, the first fan-out segment is located in the first routing area, the second fan-out segment is located in the second routing area, and an inflection point of the first fan-out segment and the second fan-out segment is located on a boundary line between the first routing area and the second routing area;
wherein the first functional area is located on a side of the first routing area away from the binding terminal, the second functional area is located on a side of the first routing area close to the binding terminal, a boundary line between the second functional area and the first routing area extends along the second direction, and a boundary line between the second functional area and the second routing area extends along the first direction.

4. The display panel according to claim 3, wherein the first fan-out segment comprises a plurality of first segments and second segments alternately arranged with each other, the first segments are connected to the second segments, and one of the second segments is arranged correspondingly to one of the anodes;
wherein the first segment is a straight line, an extension line of the first segment intersects the anode, and an orthographic projection of the second segment on the anode layer is arranged on a periphery of the anode.

5. The display panel according to claim 4, wherein a projection of the second segment on the anode layer is spaced apart from the anode, and a shape of the second segment is the same as a sharp of a part of an outer contour of the anode.

6. The display panel according to claim 5, wherein an extension line of the first segment passes through a geometric center of the anode.

7. The display panel according to claim 6, wherein one end of the first fan-out segment away from the second fan-out segment is electrically connected to the data line through the first via, an orthographic projection of the first via connected to one of adjacent two first fan-out segments on the second metal layer overlaps with the second segment, and an orthographic projection of the first via connected to the other of adjacent two first fan-out segments on the second metal layer is spaced apart from the first segment.

8. The display panel according to claim 6, wherein the second metal layer further comprises a plurality of first functional lines extending along the second direction, the first functional lines are located in the first functional area, one of the first fan-out segments corresponds to and is disposed separately from one of the first functional lines, a shape of the first functional lines is the same as a shape of the first fan-out segments, and one of the first functional lines is partially collinear with one of the first fan-out segments.

9. The display panel according to claim 8, wherein the second metal layer further comprises a plurality of second functional lines extending along the second direction, the second functional lines are located in the second routing area, one of the first fan-out segments corresponds to and is disposed separately from one of the second functional lines, a shape of the second functional lines is the same as a shape of the first fan-out segments, the second functional line comprises a plurality of first functional segments separately disposed from each other, one of the first functional segments corresponds to one of the anodes, and one of the second functional lines is partially collinear with one of the first fan-out segments.

10. The display panel according to claim 9, wherein the second metal layer further comprises a plurality of third functional lines extending along the first direction, the third functional lines are located in the functional routing area and the first routing area, and one of the second fan-out segments corresponds to and is disposed separately from one of the third functional lines;
wherein the third functional line comprises a plurality of second functional segments disposed separately from each other, the second functional segments are located between any two adjacent first fan-out segments, and one of the third functional lines is collinear with one of the second fan-out segments.

11. The display panel according to claim 10, wherein a length of any third functional line located in the first routing area is shorter than a length of any third functional line located in the functional routing area.

12. The display panel according to claim 10, wherein the display panel comprises a constant-voltage high-level signal, and at least one of the first functional line and the third functional line is connected to the constant-voltage high-level signal.

13. The display panel according to claim 10, wherein at least one second fan-out segment intersects with the first functional segments distributed along the first direction, and at least two second fan-out segments are located between two adjacent first functional segments.

14. The display panel according to claim 6, wherein the second metal layer further comprises a plurality of first functional branch lines extending along the second direction, the first functional branch lines are located in the second functional area, a shape of the first functional branch lines is the same as a shape of the first fan-out segments, and a distance between two adjacent first functional branch lines in the first direction is the same as a distance between two adjacent first fan-out segments in the first direction.

15. The display panel according to claim 5, wherein an inflection point of the first fan-out segment and the second fan-out segment is located on the first segment or on the second segment.

16. The display panel according to claim 4, wherein the display panel comprises a plurality of sub-pixels distributed in an array, and an orthographic projection of an extension line of the first segment on the anode layer intersects the anodes of the sub-pixels of the same color.

17. The display panel according to claim 1, wherein the display panel further comprises a plurality of driving transistors distributed in an array, and the driving transistor comprises:
an active part disposed on the substrate;
a gate disposed on a side of the active part away from the substrate;
a source and a drain disposed on a side of the gate away from the substrate;
wherein the source and the drain are located on the first metal layer, and the source and the drain are electrically connected to the anode through a second via.

18. The display panel according to claim 17, wherein the display panel further comprises an anode reset line extending along the second direction, the anode reset line is disposed on the same layer as the gate, and an orthographic projection of the first fan-out segment on the substrate partially overlaps an orthographic projection of the anode reset line on the substrate.

19. The display panel according to claim 1, wherein the second fan-out segment is a straight line, in a direction close to a center line of the display panel along both sides of the display panel in the second direction, a length of the second fan-out segment increases gradually.

20. The display panel according to claim 1, wherein the first metal layer further comprises first voltage signal lines parallel to and spaced from the data lines, and at least a part of an orthographic projection of the second fan-out segment on the first metal layer overlaps a part of the data lines and/or a part of the first voltage signal lines.

21. (canceled)
